(19) United States
(12) Patent Application Publication
(10) Pub. No.: US 2008/0136425 A1
(43) Pub. Date: Jun. 12, 2008

(54) Device for detecting the state of steel-reinforced concrete construction parts

(76) Inventors: Alexander Holst, Braunschweig (DE); Stefan Bruder, Konigslutter am Elm (DE); Hans-Joachim Wichmann, Braunschweig (DE)

Correspondence Address: SALTER & MICHAELSON;THE HERITAGE BUILDING, 321 SOUTH MAIN STREET, PROVIDENCE, RI, 029037128, US

(21) Appl. No.: 11/810,231

(22) Filed: Jun. 5, 2007

(30) Foreign Application Priority Data
Dec. 8, 2006 (DE) 20 2006 018 747.2

(51) Int. Cl. G01R 27/08

(52) U.S. Cl. 324/691

(57) ABSTRACT

A device for detecting the state of steel-reinforced concrete construction parts, having one or more sensor wires disposed at different distances from a surface of the concrete construction part. The wires are subjected to the corroding influence of the environment of the concrete construction part. The device also includes a measuring instrument, which measures the volume resistance of the sensor wires and an evaluating device, which can supply the measurement values of the measuring instrument either permanently and/or when called up, and which, evaluating from these values, draws conclusions on the depth-dependent corrosion state of the concrete construction part.

### TECHNICAL FIELD

The invention relates to a device for detecting the state of steel-reinforced concrete construction parts.

### BACKGROUND OF THE INVENTION

The corrosion of steels in concrete is one of the most important causes of damage in steel-reinforced and pre-stressed concrete structures. The considerable dangers that can ensue from damaged concrete structures lead to the fact that there is an interest in knowing how far possible damage of the steel in concrete has progressed.

The growing trend toward preservation of structures and the knowledge that a timely recognition of damage makes possible a prevention or suitable corrective measures and, in any case, can reduce the danger of damage to the surroundings of the structure intensifies interest in better measurement methods.

In the past, it has generally been attempted to establish the state of corrosion of steel reinforcements of solid structures by a visual inspection of accessible regions of the surface of the structure by examining optically the rust discolorations and cracks on the concrete surface. One possibility is known, for example, from DE 20 2006 001 718 U1, to arrange strain gauges on structures and to draw conclusions on the deformations of the concrete from the corresponding measurements, considering here that it is possible that the deformations could have occurred due to corrosion of steel parts. A sounding with a hammer or the performing of an endoscopy is also considered.

In all of these cases, an actually determined corrosion of steel reinforcements is only recognized at a relatively late stage. These inspections are nevertheless conducted at regular time intervals, for example, in the case of civil engineering structures, within the scope of streets and roads, e.g., in bridges, according to DIN 1076. They establish only the respective instantaneous state, however, and the reliability of their information is also very limited.

In addition, it has already been attempted to detect, by means of other sensors, not the corrosion itself, but rather several corrosion-influencing parameters. The chloride content, the pH, the moisture or the temperature in the environment of the affected structure can be established with this sensor technique relative to specific parameters.

An example is given, e.g., in DD 301,230 A7, in which a sensor is proposed for determining, among other things, the moisture in concrete. In this case, two electrodes, which use the electrical resistance of the measurement path between the two electrodes to determine the moisture, are inserted into the concrete.

Another method for the fiber-optical determination of moisture and a suitable device for this are known from DE 199 42 317 A1, in which a water-insoluble polymer matrix is used with a dye and subsequently, by means of spectral or fiber-optic evaluation, respectively, conclusions are drawn relative to the moisture present inside the structural components.

These methods are also very indirect measurement possibilities and the reliability of their information is very limited, but nevertheless conclusions must also be drawn therefrom.

Finally, a test to detect specific magnitudes of the corrosion state that are determined by means of a type of substitute sensor technique is known. In this case, the detection of the concrete resistance, of the potential or also of the corrosion current was made possible as an electrochemical value. Sensors that would be suitable for this purpose are usually only applicable a priori; therefore, they must be incorporated in the region of the concrete covering during the first construction of the concrete structure. Such sensors are also very complicated in their production and are relatively costly. In addition, they sometimes possess only a very limited service life and may even represent additional weak spots in the construction part due to the size of the sensors inserted. Here, the sensors thus simultaneously represent a weakening of the concrete joint and, as a consequence, may possibly lead to a premature corrosion of the steel reinforcement in the concrete structure. Finally, the recorded measurement values based on multi-parameter dependence are only limited and thus cannot be reliably interpreted. Special devices are also usually necessary for reading out the corresponding sensors.

An electrode assembly for a corrosion measurement system for determining the corrosion of metal embedded in a construction part, for example, concrete, is known from DE 197 06 510 C1. Here, a corrosion measurement with a very complicated construction and technically demanding elements is targeted.

A corrosion sensor technique has been proposed in individual cases, but these require sensors that can be utilized in the individual case and that are very large, complicated in terms of measurement technology and therefore very expensive; however, a desired, universally applicable sensor technique has not been considered. In addition, the sensor techniques are for the most part unsuitable for nondestructive measurement.

In practice, however, there are still no reliable measurement methods that are nondestructive. It has always previously been necessary to remove a structure of interest or a corresponding construction part, respectively, or to take a drilled core or corresponding drillings, respectively, and to investigate these more closely in a laboratory or at other suitable testing sites.

Therefore, an object of the present invention is to propose a possibility for how the knowledge of the state of corrosion damage within concrete structures can be improved.

### SUMMARY OF THE INVENTION

This object is accomplished by a device for detecting the state of steel-reinforced concrete construction parts, having one or more sensor wires disposed at different distances from a surface of the concrete construction part, the wires being subjected to the corroding influence of the environment of the concrete construction part; having a measuring instrument, which measures the volume resistance of the individual sensor wires; and having an evaluating device, which can supply the measurement values of the measuring instrument either permanently and/or when called up, and which, evaluating from these values, draws conclusions on the depth-dependent state of the concrete construction part.

The invention makes it possible to create a wire sensor technique for the evaluation of the corrosion threat to concrete steel reinforcements and pre-stressed steel reinforcements in concrete structures, whereby this wire sensor technique is suitable both for direct [initial] incorporation as well as also for later incorporation.

The state detection here thus relates to the corrosion state, also including the threatened state of corrosion for a steel reinforcement that by itself is understood as not yet corroding.

It is thus possible to insert the invention during the initial construction in new structures of construction works, for example, of bridges or parking decks. Likewise, however, it is also possible to perform a later incorporation into already existing structures.

Thus, a type of corrosion monitoring is possible. The wire sensor technique creates a sensor for corrosion, or stated more precisely, for the state of corrosion of the steel reinforcement in a concrete construction part that is only threatening, but has still not begun. In this case, a volume resistance measurement of the wire is utilized.

It is made possible for the first time by means of the invention to locally detect the depth-dependent progress of the depassivation front, for example, due to input of chloride into the concrete, which leads to the corrosion of the steel reinforcement. The invention makes possible a detection and monitoring of the corrosion danger, thus of the depth-dependent beginning of corrosion.

If the wire diameter of the sensor wires is reduced, the corrosion progress can also be detected via a resistance measurement by means of one embodiment of a device according to the invention.

This measurement principle of volume resistance measurement that has not yet been utilized for this case of application is supported by a design which is board-based. The latter has very thin wires and can be used roughly in the form of a sensor pin, for example, of a mortar pin, as a sensor support with sensor wires also for later incorporation.

Thus, a depth-dependent diagnosis of the corrosion risk and/or the corrosion progress will be made in the concrete. The corrosion monitoring of steel reinforcements is possible in concrete construction parts both in the case of pre-stressed steel reinforcements as well as in the case of configurations that are not pre-stressed.

Another optimization of the design according to the invention can result, for example, by employing simplified accelerated time conditions in the laboratory test. The practical suitability has already been demonstrated by a test application of sensors on in-situ constructions of steel-reinforced concrete.

The invention is characterized by considerable technical and economic advantages. A simple measurement principle is utilized, so that the data determined can be read out reliably and without problem with resistance meters (ohmmeters) that can be obtained in a relatively cost-effective manner. Standard resistance meters may be utilized. This simple manipulation also has the advantage that specialists need not be brought in.

The invention is suitable both for sporadic, occasional measurements as well as also for monitoring, thus a permanent or regular (also continuous) measurement.

The device according to the invention can be constructed small and for manual use. Its positioning is thus simple and it can be transported to the site of application also without problem. The devices can be miniaturized still further if necessary.

In addition, it is possible to produce a large number of the same specific design type, which still further and clearly reduces costs with an appropriate serial manufacture.

Since it is possible to produce the necessary wire sensors in a comparatively inexpensive manner and, in addition, the costs for installing them are also still relatively low, the total costs for the corrosion diagnoses that are to be conducted and also regular corrosion monitoring are additionally clearly reduced. It is therefore also possible to conduct diagnoses and monitoring that were not previously possible, or it is possible now to perform a diagnosis with a very much larger number of sensors while costs remain constant, and thus to essentially improve the total knowledge of the concrete structure to be tested. The lower cost range of the sensors themselves thus makes possible a broader application potential when compared with conventional tests for increasing knowledge on the corrosion state inside the concrete structure.

An identification of different and in part very different types of threatening corrosion damage to reinforcement steels in steel-reinforced concrete and pre-stressed concrete construction parts is possible, for example, of chloride-induced or also carbonatizing-induced corrosion damage.

Examples of particularly interesting areas of application are, e.g., bridges and parking decks, in which corrosion damage due to road salts is becoming increasingly known and a timely recognition is particularly important due to the permanent load. The assurance of corrosion protection of pre-stressed elements in pre-stressed concrete construction in the case of bridges is to be named in particular here.

The design according to the invention is also suitable for monitoring the success of reconstruction after corrective maintenance of corrosion-damaged steel-reinforced concrete structures.

In the case of board production, only known and comparatively cost-favorable steps are necessary, e.g., the soldering of sensor components, wherein, for example, SMD (surface mounted device) resistances can be used, which can offer the advantage of an almost complete temperature independence, in addition the production of cable terminals, and finally, the assembly of the sensor support material, for example, a sensor pin.

Other advantages lie in the fact that the design according to the invention does not possess a significant temperature dependence. The temperature fluctuations that typically occur on structures therefore have only a small influence. The initially described conventional electrochemical sensors, in contrast, usually have a very strong temperature dependence.

Unlike previous designs, the invention operates with a volume resistance measurement, thus a different measurement principle. Due to the board-based design with very thin wires and the use of a sensor pin for later installation, cases of application are opened up that previously did not permit corrosion sensor techniques.

Also conceivable is a design with only one sensor wire, in order to indicate only the reaching of a certain depth through the depassivation front in the concrete part, e.g., for triggering certain steps.

Devices with only one sensor wire also have advantages associated with specific microcontroller maskings.

In the case of very precisely operating measuring instruments, there is also the possibility of evaluating the changing resistance of a wire sensor during the process until it is thoroughly corroded and/or to apply the wire sensors in more complex loops that do not lie only at a constant depth each time.

### DESCRIPTION OF THE DRAWINGS

An example of embodiment of the invention is more closely described below on the basis of a drawing. Shown are:

FIG. 1 a simplified schematic representation, which illustrates the course of damage of a steel-reinforced concrete structure over time;

FIG. 2 a schematic representation of a section through a concrete construction part perpendicular to a selected steel reinforcement;

FIG. 3 a schematic representation of a first embodiment of the invention in a first representation;

FIG. 4 a schematic representation of the first embodiment of the invention in another representation;

FIG. 5 a schematic representation of a second embodiment of the invention in a first representation;

FIG. 6 a schematic representation of the second embodiment of the invention in a second representation;

FIG. 7 a schematic representation of an element of the invention in a first representation; and

FIG. 8 a schematic representation of the element of FIG. 7 in a second view.

### DETAILED DESCRIPTION

It is shown in FIG. 1 how the extent of damage to a steel-reinforced concrete construction part 10 changes over time. Time t is plotted on the right and damage S is plotted at the top, whereby an arbitrary scale can be taken for damage S. The time scale begins with the construction of steel-reinforced concrete construction part 10. During a first time segment, damage occurs from the surface of the construction part from the penetration of a depassivation front into the concrete. This can result, for example, due to a carbonatizing of the concrete, which occurs when carbon dioxide from the air reacts with the alkaline components of the cement. As a consequence, the pH decreases and the alkaline protection of the steel is lost. Then the steel begins to corrode. Another cause of depassivation may be the penetration of chlorides into the concrete, which can occur, for example, when the concrete construction part is used, e.g., as a roadway or is found in the vicinity of a roadway onto which road salt is distributed.

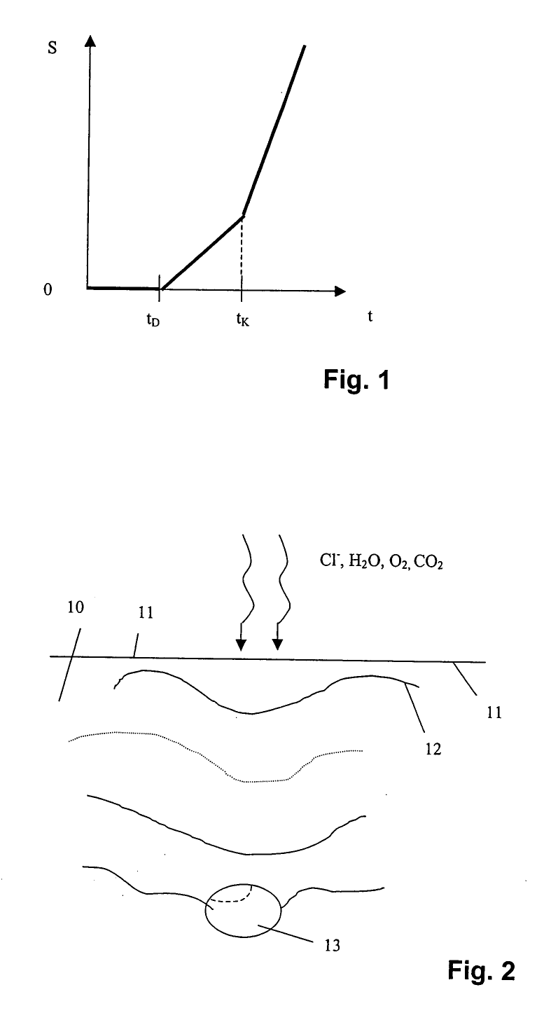

This depassivation front 12 at first does not yet contact the steel reinforcement 13 of a concrete construction part 10 itself, but only penetrates progressively from the surface 11 into the concrete, as this is illustrated schematically, e.g., in FIG. 2. It is shown in FIG. 2 how the depassivation front 12 progressively penetrates continually deeper from the surface 11 into the concrete over time, until it finally reaches the steel reinforcement 13 shown in the section. At this time, the corrosion of the steel begins, if sufficient oxygen (O₂) and water (H₂O) are present on the steel.

A glance at FIG. 1 shows in turn that at this time tₒ, a second segment or a second stage of damage S begins which now attacks the steel reinforcement in a concrete manner, unlike in the first stage. Thus, the corrosion phase has started with this beginning of corrosion tₒ. After a certain time, the steel reinforcement is then thoroughly corroded. At this time t_{K} a third stage begins, since, due to the failure of the steel reinforcement 13 or the rusting throughout of a support, respectively, under certain circumstances, the bearing safety or stability of the concrete construction part 10 is no longer assured and now additional damage and even a caving in of the construction may occur in some cases.

From this schematic representation in FIGS. 1 and 2, it can be assumed that it is of interest to follow the progression of the front 12 in the direction toward the steel reinforcement 13. If it is desired, intervention can be made in a timely manner, each time prior to the time when damage reaches the steel reinforcement 13; for example, repairs or replacement of the contaminated parts of the concrete construction part 10 can be made prior to the time when the corrosion of steel reinforcement 13 has generally begun.

On the other hand, when a concrete structure has already been affected, it is also of interest to establish how far the front 12 has already progressed.

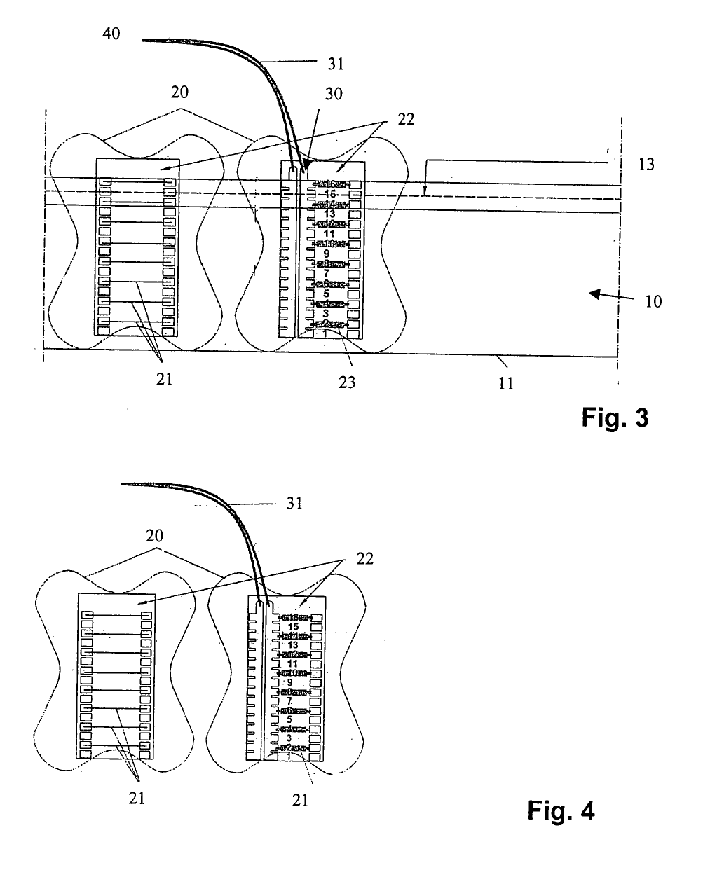

In FIG. 3, a first embodiment of the invention is shown schematically in more detail. Here, an embodiment is involved that is suitable for initial installation. This means that this device for detecting the state of steel-reinforced concrete construction parts 10 will be incorporated from the beginning by sealing it in during the production of the concrete construction part.

A concrete construction part 10 in turn can be seen schematically. A surface 11 of concrete construction part 10 is shown at the bottom in this case and the concrete construction part 10 can continue toward the top in the drawing to an extent that is selected arbitrarily.

In concrete construction part 10 there is found a reinforcement bar 13, which in this case—as also in practice—extends frequently inside it, usually parallel to the surface 11 of the concrete construction part 10. The progression of a depassivation front from the surface 11 of the construction part into the concrete construction part 10 will now be monitored or established, respectively, in the direction of the reinforcement bar or the steel reinforcement 13.

A corresponding device has here a sensor support 20, which can be, e.g., a reinforcement spacer made of concrete, as it is utilized in any case in concrete construction part 10 for attaching the bearing of the construction part reinforcement. Onto this spacer, which is used here as sensor support 20, several sensor wires 21 disposed at different distances from the surface 11 of concrete part 10 are now installed parallel to one another, for example, adhered onto spacer 20 prior to the final production of concrete construction part 10. In practice, sensor wires 21 will be arranged on a sensor board 22, for example, soldered onto it, and then the sensor board 22 will be adhered onto the spacer or the support 20, respectively.

These sensor wires 21 are very thin steel wires, which are subjected to the corroding influence of the environment of the concrete construction part 10. This means that a depassivation front 12 progressing from the surface 11 into the concrete construction part 10 also progresses along the device for state detection and reaches the sensor wires 21, one after the other.

Since thin steel wires are involved (and these are different than the steels utilized for the reinforcement bars 13), the sensor wires 21 will be rapidly corroded throughout under the effect of the depassivation front 12 after it has reached these wires.

The sensor wires 21 on sensor board 22 are connected to a measuring instrument 30, which measures the volume resistance of the preferably parallelly connected sensor wires 21.

In order to be able to perform this measurement in a particularly appropriate manner and to well identify the individual sensor wires 21, a series resistor 23, for example, an SMD series resistor is provided for each sensor wire 21. These series resistors 23 each have a different size, so that after the thorough corrosion of one sensor wire 21, it can be immediately established which sensor wire 21 is now thoroughly corroded and thus a practically infinite volume resistance is obtained at the site that has been thoroughly corroded. In fact, the change in the total resistance which occurs in the dropping out of the conducting connection through the now thoroughly corroded sensor wire 21 can be established.

The measuring instrument 30 is connected in turn to an evaluating device 40, so that the measurement values will be guided to it from the measuring instrument 30 and by evaluating these values, conclusions will be drawn on the depth-dependent state of concrete construction part 10. An increase in resistance will be recorded for the measured total resistance of the circuit due to the failure of one sensor wire 21, which is caused by the corrosion. The magnitude of this increase depends on the size of the respective series resistor 23 that is affected. Consequently, this increase can be utilized for the identification of the sensor wire 21 that has been thoroughly corroded. Since its position is known, the evaluating device 40 can recognize the depth to which corrosion conditions have actually reached. This evaluating device 40 recognizes from the measurement values namely that a depassivation front 12 has reached a specific depth or a specific distance, respectively, from the surface 11 of concrete construction part 10.

Usually, the depassivation front 12 (compare FIG. 2) progresses continually in one direction, i.e., from the surface 11 and passes still further into the depth of the concrete construction part 10. This means that the individual sensor wires 21 have thoroughly corroded one after the other from surface 11, and the measuring instrument 30 establishes this circumstance by means of a continually increasing resistance of the total structure.

It is possible, however, that this is not the case, due to the non-homogeneous distribution of the concrete inside concrete construction part 10, for example, as a result of defective sites, due to the actual arrangement of the reinforcement bars 13 or also due to other external influences, and the depassivation front 12 leads to a corrosion of a deeper-lying sensor wire 21 before another sensor wire 21 that lies closer to the surface 11 is thoroughly corroded. These effects can also be established by the measuring instrument 30, in particular, since each individual sensor wire 21 can be identified, e.g., by different series resistances each time.

The evaluating device 40 can then draw the appropriate conclusions. In this case, the measurement values of the measuring instrument 30 can be read out manually at certain intervals by means of standard ohmmeters. Simultaneously or alternatively, however, a continuous observation (monitoring) of the state of corrosion is also possible in conjunction with a data workup device.

In FIG. 3, in the center of the figure, a front side of the corresponding device can be seen, in which the series resistances 23 are symbolically depicted. The reinforcement spacer or support 20, respectively, may also be recognized as an approximately X-shaped structure.

To the left of this presentation in the same FIG. 3 is the back side of a corresponding device for state detection, on which the thin sensor wires 21 themselves can be recognized even more clearly.

Cables 31 that are soldered to sensor boards 22, which connect sensor boards 22 to the measuring instrument 30, can also be seen. These cables 31 here run inside concrete construction part 10 and cannot be recognized from the outside, since they can be installed by sealing them in during the production of concrete construction part 10.

FIG. 4 presents the same constellation with an illustration of the device for state detection from the front (right) and from the back (left) as well as the cables 31 connecting thereon to sensor board 22 on the reinforcement spacer 20, this time omitting the concrete construction part 10 (FIG. 3) for purposes of better clarification. The back side of sensor board 22 with the series resistances 23 and the soldering sites in the region where cables 31 are connected can be protected over the entire surface with an epoxy resin in order to prohibit corrosion (not shown in FIGS. 3 and 4).

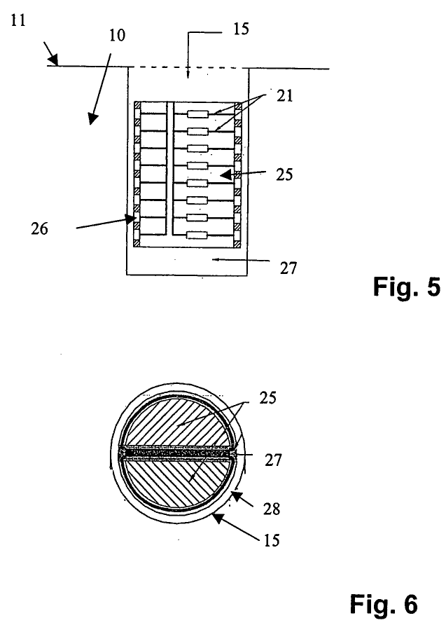

A second embodiment of a device according to the invention is shown in FIG. 5. This embodiment is suitable for the case of later installation. That is, it is frequently also of interest to equip an already existing concrete construction part 10 with this device at a later time for such detection of [corrosion] states. In this case, a drilled hole 15 must be introduced into the inside of concrete construction part 10 through the surface 11. Insofar as this is possible, this drilled hole should not destroy or attack the steel reinforcement 13 itself, but should be suitable for introducing the device for detecting the state of the steel-reinforced concrete construction part 10 according to the invention to a sufficient depth.

Such a device is prefabricated in this case, whereby a serial production is possible without anything further. Here, a mortar pin 25 is used as support 20, and this can be particularly well recognized in FIG. 6. This cement mortar pin 25 is approximately semi-cylindrical and is provided all around with grooves 26.

In this case, a sensor board 22 will be installed between the two cylinder halves of the cement mortar pin 25 or of the support 20, respectively, whereby this sensor board 22 may in turn support series resistances 23 etc. The sensor wires 21 are guided onto the outside of the cylinder into the mentioned grooves 26 and are soldered to the sensor board 22.

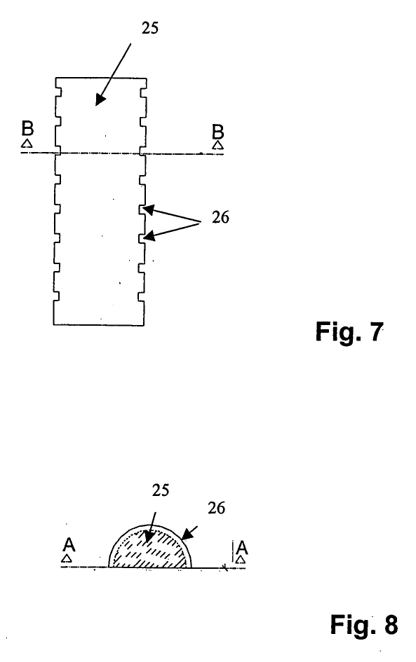

These grooves 26 can be particularly well recognized in FIG. 7, in which the mortar pin 25 is shown on an enlarged scale. For corrosion protection, the sensor board 22 itself is in turn coated over the entire surface with an epoxy resin.

Mortar pin 25 with sensor wires 21 is seen in turn in the drilled hole 15 in FIG. 5. Here, an example is shown having eight individual wires, each of these having SMD resistances, on a mortar pin 25.

In addition, filling mortar 27 is provided under mortar pin 25 in order to make the installation more precise.

The filling mortar 27 is also introduced in order to join the cement mortar pin 25 flush with the wall of the drilled hole after it has been introduced into the drilled hole 15 and in order to produce the joint with the old concrete of concrete construction part 10, since the sensor wires 21 will in fact be in contact with the corroding influence of the direct environment inside the concrete construction part 10 and will sense the state prevailing therein.

In order to prevent the occurrence of capillary-like effects in the drilled hole 15 between the mortar pin 25 and the wall of the drilled hole or to prevent moisture from outside the concrete construction part 10 from migrating through the surface 11 into the annular cylinder space, the drilled hole 15 may additionally be sealed relative to the outside with an epoxy resin gasket 28 in the region of surface 11, which is shown in FIG. 6.

In the case of a later installation of a mortar pin 25 or another suitable support 20 with wire sensors 15 into a concrete construction part 10, it is possible only with difficulty to effect the connection of the sensor wires 21 to the measuring instrument 30 and/or the connection of the measuring instrument 30 to the evaluating device 40 by means of cables 31. Since the mortar pin 25 is introduced from the outside through the surface 11 into the concrete construction part 10, there is provided only the possibility of also connecting a cable 31 from this outer side through the surface 11.

Under certain circumstances, this is optically not desired, since it involves the side of a concrete structure that is in full view, or when it involves, e.g., the surface 11 on the upper side of a parking deck.

Alternatively, the cable 31 may also be guided into the inside of the concrete construction part 10 to the opposite-lying surface. This is recommended in the case of endangered steel-reinforced concrete construction parts 10, for example, bridge roadway plates or parking decks.

Frequently, however, there is the possibility of making such measures within the scope of a reconstruction and then to arrange the cables 31 under the newly introduced surface 11 of the concrete construction part 10, wherein static points of view are to be taken into consideration.

Tests have also shown that a wireless or cable-free transfer of the measurement values from the measuring instrument 30 inside concrete construction part 10 to the evaluating device 40 at an adjacent site or even at a site lying further distant should be possible. This can be accomplished via radio, optionally also reading out the measurement values of the measuring instrument 30 introduced under the surface 11 by means of an inductive method or other type of polling at specific time intervals, and in this way the values are delivered to evaluating device 40.

A horizontal section B-B from FIG. 7 can be seen again in FIG. 8, and this shows that grooves 26 project around the cylinder wall of the mortar pin 25.

The thorough rusting of thin, deep-stacked iron filaments that are arranged in the region of the concrete surface 11 and that have a diameter from 50 μm to 5000 μm, particularly from 65 μm to 500 μm, will be monitored online or offline with the described board-based wire corrosion sensor. The corrosion-induced break of a single wire can be identified by a measurement of the volume resistance of a sensor wire 21 comprising an individual wire, since resistance gaps of 2 to 4 decades are generated by the corrosion-induced breaking of the wire. In the case of several parallelly connected sensor wires 21, the respective resistance gap turns out to be smaller due to complete corrosion, but it is also well measurable.

The sensor with the sensor wires 21 may either be unprotected, thus to a certain extent naked, or, however, it may also be incorporated into construction part 10, after it has been provided initially with a thin mortar layer, onto a sensor support 20, wherein the sensor support may be a concrete spacer, for example.

For a later application of the device according to the invention for detecting the state of steel-reinforced concrete construction parts 10 by means of the wire sensor, a mortar pin 25 with back-side sensor board 22 and sensor wires 21 installed in prepared grooves 26 can be incorporated in a drilled hole and can be sealed in the region of the concrete surface 11. The subsequent incorporation of the sensor can be accomplished, e.g., by a shrinkage-compensated application mortar of very small layer thickness.

In order to keep the number of necessary measurement channels or cables 31 as small as possible, the sensor wires 21 can be connected in parallel. Based on the resistance gap generated by the failure of one individual wire 21 due to corrosion, an SMD resistance 23 between approximately 0.1 k Ohm and approximately 5 k Ohm can be connected in series for each sensor wire 21. The thoroughly corroded sensor wire 21 can be identified with the use of variable series resistances. Individual wire sensors without series resistor could also be used.

What is claimed is:

1. A device for detecting the state of steel-reinforced concrete construction parts, having one or more sensor wires disposed at different distances from a surface of the concrete construction part, the wires being subjected to the corroding influence of the environment of the concrete construction part; a measuring instrument, which measures the volume resistance of the sensor wires; and an evaluating device, which can supply the measurement values of the measuring instrument either permanently and/or when called up, and which, evaluating from these values, draws conclusions on the depth-dependent corrosion state of the concrete construction part.

2. The device for state detection according to claim 1, wherein each sensor wire has a different volume resistance, relative to the other sensor wires, which is produced by its own resistance and/or by a series resistor.

3. The device for state detection according to claim 2, wherein the sensor wires are connected in a cascade or in parallel, respectively, and that the different volume resistances are utilized for identifying the corroding sensor wire in each case.

4. The device for state detection according to claim 1, including a support for the sensor wires utilized for common incorporation into the concrete construction part.

5. The device for state detection according to claim 4, wherein the support has a mortar pin, which supports the sensor wires.

6. The device for state detection according to claim 5, wherein the mortar pin is provided with grooves, in which the sensor wires are disposed.

7. The device for state detection according to claim 6, wherein the mortar pin is constructed of two approximately semi-cylindrical element parts, and that a sensor board is provided between the two semi-cylindrical element parts, and this board bears the electronic components including any possible series resistances.

8. The device for state detection according to claim 2, including a support for the sensor wires utilized for common incorporation into the concrete construction part.

9. The device for state detection according to claim 8, wherein the support has a mortar pin, which supports the sensor wires.

10. The device for state detection according to claim 9, wherein the mortar pin is provided with grooves, in which the sensor wires are disposed.

11. The device for state detection according to claim 10, wherein the mortar pin is constructed of two approximately semi-cylindrical element parts, and that a sensor board is provided between the two semi-cylindrical element parts, and this board bears the electronic components including any possible series resistances.

12. The device for state detection according to one of claim 1, wherein an SMD resistance, in particular with a resistance value between 0.1 k Ohm and 10 k Ohm is connected in series with each sensor wire.

13. The device for state detection according to one of claim 3, wherein an SMD resistance, in particular with a resistance value between 0.1 k Ohm and 10 k Ohm is connected in series with each sensor wire.

14. The device for state detection according to claim 1, wherein each sensor wire is an iron filament with a diameter of 50 μm to 5000 μm.

15. The device for state detection according to claim 3, wherein each sensor wire is an iron filament with a diameter of 50 μm to 5000 μm.

16. The device for state detection according to claim 1, wherein between 1 and 20 sensor wires are utilized.

17. The device for state detection according to claim 3, wherein between 1 and 20 sensor wires are utilized.

18. The device for state detection according to claim 5, wherein the mortar pin possesses a diameter between 5 mm and 100 mm, and in particular between 8 mm and 30 mm.
